(19) United States
(12) Patent Application Publication
(10) Pub. No.: US 2006/0185590 A1
(43) Pub. Date: Aug. 24, 2006

(54) High temperature chemical vapor deposition apparatus

(75) Inventors: Marc Schaepkens, Medina, OH (US); Demetrius Sarigiannis, Medina, OH (US); Lakshmipathy Muralidharan, Tamil Nadu (IN)

Correspondence Address: GEAM - QUARTZ;IP LEGAL, ONE PLASTICS AVENUE, PITTSFIELD, MA, 01201-3697, US

(73) Assignee: General Electric Company

(21) Appl. No.: 11/291,558

(22) Filed: Dec. 1, 2005

Related U.S. Application Data
(60) Provisional application No. 60/654,654, filed on Feb. 18, 2005.

(51) Int. Cl. C23C 16/00

(52) U.S. Cl. 118/715; 427/248.1; 118/725

(57) ABSTRACT

Embodiments for an apparatus and method for depositing one or more layers onto a substrate or a freestanding shape inside a reaction chamber operating at a temperature of at least 700° C. and 10 torr are provided. The apparatus is provided with means for defining a volume space in the reaction chamber for pre-reacting the reactant feeds forming at least a reaction precursor in a gaseous form, and a volume space for depositing a coating layer of uniform thickness on the substrate from the reacted precursor. In one embodiment, the means for defining the two different zones comprises a distribution medium separating the pre-reaction zone from the deposition zone, for uniform distribution of the reacted precursor on the substrate. In another embodiment, the means for defining the two different zones comprises a plurality of reactant feed jets or injectors, for creating a jet-interaction zone or pre-reactant zone separate from a deposition zone, for deposing the reacted precursor on the substrate.

### CROSS REFERENCE TO RELATED APPLICATION

This application claims priority to U.S. Provisional Patent Application No. 60/654654, which was filed 18 Feb. 2005, which patent application is fully incorporated herein by reference.

### FIELD OF INVENTION

The present invention relates to a high temperature chemical vapor deposition apparatus.

### BACKGROUND OF THE INVENTION

Chemical vapor deposition (“CVD”) is a widely used production process for the application of a coating to a substrate, as well as for the fabrication of freestanding shapes. In a CVD process, the formation of the coating or the freestanding shape occurs as a result of chemical reactions between volatile reactants that are injected into a reactor containing a heated substrate and operating at sub-atmospheric pressure. The substrate could be part of the final coated product, or could be sacrificial in the case of fabrication of freestanding shapes. The chemical reactions that are responsible for the formation of the coating or freestanding products are thermally activated, taking place either in the gas-phase, on the substrate surface, or both. The reaction is very much dependent on a number of variables, including reactant chemistries, reactant flow rates, reactor pressure, substrate temperature, reactor geometries, and other hardware and process parameters.

CVD reactors, particularly low temperature CVD reactor configurations, have been used for applications such as thin film depositions for semiconductor device fabrication, or for the coating deposition of various reactant chemistries. High temperature CVD reactor configurations have been used to deposit coatings on graphite substrates for use in heater applications; or to deposit freestanding shapes like pyrolytic boron nitride crucibles for III-V semiconductor crystal growth. In prior art reactor configurations when the substrate is heated to relatively low temperatures, i.e. less than 1000° C., most chemistries will form a deposit on the substrate through a reaction limited deposition mechanism, where the chemical reactions mainly take place at the substrate surface, as is illustrated in FIG. 1. The resulting deposits that are formed at relatively low temperatures, i.e., in the reaction-limited regime, may be highly uniform in thickness and chemistry, but their deposition rates are typically relatively low, dependent on operating pressure and flows.

In the prior art reactor configurations for relatively high substrate temperatures, i.e. >1000° C., most chemistries will form a deposit 4 on the substrate 5 through a mass transport limited mechanism as illustrated in FIG. 2. In the mass transport limited regime, or near the transition between the mass transport limited and reaction limited regime, the chemical reactions can take place at the surface but also in the gas-phase.

In an example of a high-T CVD process such as the deposition of pyrolytic boron nitride (PBN), it is well accepted that BCl₃ and NH₃ reactants form intermediate species, including but not limited to Cl₂BNH₂. The intermediate species are subsequently transported to the substrate surface to go through additional chemical reactions, forming PBN deposits and reaction by-products, including but not limited to HCl. An example of a prior art high T CVD reactor configuration is shown in FIG. 3, for a chamber 11 to deposit coatings or forming freestanding shapes. The chamber 11 contains an assembly of resistive heating elements 55 and a flat substrate 5. Reaction gases 1-3 enter and exhaust the gas chamber through exhaust lines 600. The deposits 4 are formed at high temperature, i.e. near the transition to or in the mass transport limited regime, with relatively high growth rates of >0.5 micron/min, dependent on operating pressure and flows. However, the deposited material in the reactor chamber of the prior art typically suffers from non-uniformities in thickness and chemistry, i.e. the deposited thickness and chemistry uniformities, expressed as the ratio of standard deviation to average, are typically larger than 10%.

There is a need for CVD apparatus configurations that provide both high uniformity and high growth rates for applications requiring both criteria, particularly for the formation of certain chemical compositions such as pBN, aluminum nitride, etc., which can only be formed at high temperatures with the desired properties. There is also a need for high temperature CVD apparatus configurations that operate near or in the mass transport limited regime to deposit materials with a highly controllable thickness and chemistry profile.

The present invention relates to improved high temperature chemical vapor deposition apparatus configurations for the fabrication of coated and freestanding products requiring a highly controllable thickness and chemistry profile, with high uniformity and at high growth rates.

### SUMMARY OF THE INVENTION

In one aspect, the invention relates to a high temperature chemical vapor deposition (CVD) system comprising a vacuum reaction chamber maintained at a pressure of less than 100 torr, housing a substrate or a free-standing object to be coated; an inlet unit connected to a reactant feed supply system for providing at least two reactant feeds to the chamber; an outlet unit from the reaction chamber; heating means for maintaining the substrate at a temperature of at least 700° C.; and means for defining a volume space in the reaction chamber for pre-reacting the reactant feeds forming a reaction precursor in a gaseous form, and a volume space for depositing a coating layer on the substrate from reacted precursor.

In another aspect of the invention, the means for defining two spatially different zones, a pre-reaction zone and a deposition zone, comprises at least a gas distribution device for uniform distribution of reacted intermediates on the substrate forming a coating layer with uniform thickness of less than 10%, expressed as ratio of standard deviation to average.

In another aspect of the invention, the means for defining two spatially different zones, a pre-reaction zone and a deposition zone, comprises a plurality of reactant feed jets for creating a jet-interaction action wherein the reactants pre-react.

In yet another embodiment, the high temperature chemical vapor deposition (CVD) system comprises a vacuum vessel containing a substrate to be coated; at least two side reactant jet inlets for feeding reactants to the vessel as well as forming and defining a pre-reaction zone; an optional central jet inlet for diluent and or reactant feed; at least one exhaust outlet, wherein the pre-reaction zone is formed as by directing the plurality of side injectors towards each other in at least one location creating a jet interaction action thus pre-reacting the reactants, and wherein the pre-reaction zone is spatially different from a deposition zone wherein the substrate is uniformly coated by the reacted precursor.

The invention further relates to a method for uniformly depositing a coating layer on a substrate with a uniform thickness of less than 10%, expressed as ratio of standard deviation to average, the method comprises the step of: a) pre-reacting reactants in a separate zone of a reaction chamber, forming at least a reaction precursor in gaseous form; and b) depositing a uniform coating layer on a substrate from the reacted precursor, wherein the reaction chamber comprises means for creating the pre-reacting zone and the deposition zone in the reaction chamber, and means for heating the substrate to a temperature of at least 700° C. and maintaining the chamber pressure to less than 100 torr.

### BRIEF DESCRIPTION OF THE DRAWINGS

FIG. 1 is a schematic diagram showing the CVD mechanism in the reaction limited (lower temperature) regime.

FIG. 2 is a schematic diagram showing the chemical vapor deposition (CVD) mechanism in the mass transport limited (high temperature) regime.

FIG. 3 is a schematic sectional view of a prior art CVD deposition apparatus.

FIG. 4 is a schematic sectional view of an embodiment of a CVD deposition apparatus of the invention.

FIG. 5 is a schematic sectional view of another embodiment of the CVD deposition apparatus of the invention.

FIG. 6 is a schematic sectional view showing one embodiment of the CVD apparatus of the invention, comprising a plurality of feed nozzles or jets defining a pre-reaction or jet-interaction zone.

FIG. 7(a) is a perspective view of the CVD apparatus of FIG. 6. FIG. 7(b) is a cut-off section view of an embodiment of the apparatus of FIG. 6, having a plurality of feed nozzles.

FIG. 8 is a graph comparing experimental results with computational fluid dynamics (CFD) model predictions the embodiment illustrated in FIG. 4.

FIG. 9 is a graph comparing the three-dimensional computational fluid dynamics (CFD) calculations of the deposition thickness profiles of the prior art apparatus of FIG. 3 with an embodiment of the present invention as illustrated in FIG. 4, showing significant improvement in uniformity in the present invention.

FIG. 10 is a graph illustrating experimental results of the deposition profiles from one embodiment of the invention, with substantially uniform distribution on the substrate.

FIG. 11 is a graph illustrating three dimensional computational fluid dynamics (CFD) calculations of the deposition rate profiles on the substrate of the embodiment illustrated in FIG. 6, showing a substantially uniform distribution as achieved on a substrate in a CVD apparatus comprising a plurality of reactant feed nozzles.

FIG. 12 is a graph illustrating computational fluid dynamics (CFD) calculations of the deposition rate and carbon concentration profiles (in the radial direction of the substrate) for carbon-doped PBN (CPBN) deposition from BCl3, NH3, and CH4, showing that substantially uniform deposition rate (and thus thickness) and carbon concentration profiles for one embodiment of the invention.

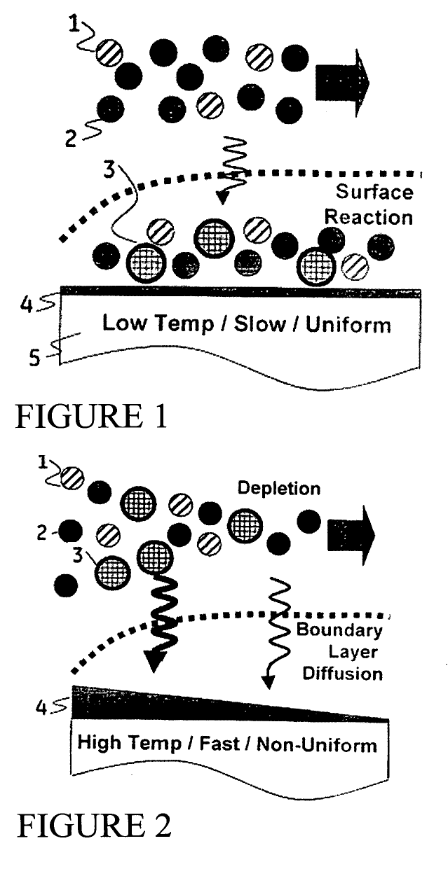

### DETAILED DESCRIPTION OF THE INVENTION

The terms “a” and “an” herein do not denote a limitation of quantity, but rather denote the presence of at least one of the referenced item. All ranges disclosed herein are inclusive and combinable. Furthermore, all ranges disclosed herein are inclusive of the endpoints and are independently combinable. Also, as used in the specification and in the claims, the term “comprising” may include the embodiments “consisting of” and “consisting essentially of.”

As used herein, approximating language may be applied to modify any quantitative representation that may vary without resulting in a change in the basic function to which it is related. Accordingly, a value modified by a term or terms, such as “about” and “substantially,” may not to be limited to the precise value specified, in some cases. In at least some instances, the approximating language may correspond to the precision of an instrument for measuring the value.

As used herein, CVD apparatus may be used interchangeably with CVD chamber, reaction chamber, or CVD system, referring to a system configured to process large areas substrates via processes such as CVD, Metal Organic CVD (MOCVD), plasma enhanced CVD (PECVD), or organic vapor phase deposition (OVPD) such as condensation coating, at high temperatures of at least 700° C., and in some embodiments, over 1000° C. The apparatus of the invention may have utility in other system configurations such as etch systems, and any other system in which distributing gas within a high temperature process chamber is desired.

As used herein, “substrate” refers to an article to be coated in the CVD apparatus of the invention. The substrate may refer to a sacrificial mandrel (a mold or shape to be discarded after the CVD is complete, and only the hardened shaped coating is kept), a heater, a disk, etc., to be coated at a high temperature of at least 700° C. in one embodiment, and at least 1000° C. in another embodiment.

As used herein, “pre-reacting” or “pre-react” means the reactants are heated and react with one another in the gas phase, forming at least a gaseous precursor or reaction intermediate; “pre-reacting phase” or “pre-reaction phase” means the phase or period in time wherein reactants are heated and react with one another in the gas phase, forming at least a gaseous precursor. As used herein, “pre-reacting zone” or “pre-reaction zone” means a volume space, a zone, space, or location within the chamber wherein the reactants react with one another in the gas phase, forming gaseous precursors.

As used herein, “deposition phase” refers to the phase or period in time wherein reactants and/or the gaseous precursors react with one another forming a coating onto a substrate. “Deposition zone” refers to a volume space, a zone, space, or location where the substrate is coated or where the reacted precursor is deposited onto the substrate. It should be noted that the deposition zone and the pre-reaction zone may not be necessarily and entirely spatially apart and there may be some overlapping in volume or space between the pre-reaction zone and the deposition zone.

As used herein, the term “jets,” “injectors” or “nozzles” may be used interchangeably and denoting either the plural or singular form. Also as used herein, the term “precursor” may be used interchangeably with “reaction intermediate” and denoting either the plural or singular form.

The invention relates to high temperature CVD (“thermal CVD”) apparatuses, and a process for producing one more layers on at least one substrate disposed in the reaction chamber of the thermal CVD apparatuses, using at least one of a liquid, a solid, or a reaction gas as a starting material or a precursor, operating at a temperature of at least 700° C. and a pressure of <100 torr. In one embodiment, the thermal CVD apparatus is for CVD depositions at >1000° C. In another embodiment, the thermal CVD apparatus is operated at a pressure of less than 10 torr. It should be noted that thermal CVD apparatus of the invention can be used for coating substrates, as well as for the fabrication of freestanding shapes.

The high temperature CVD apparatus of the invention is provided with means to allow the reactant to be preheated and/or pre-react forming volatile reaction intermediates in a pre-reaction zone, prior to the deposition phase in a deposition zone. In the apparatus of the invention, the pre-reaction zone is spatially apart from the deposition zone, allowing the reactants to have a sufficient residence time for the homogeneous gas-phase conversion of reactants to precursors (reaction intermediate species). The spatial separation of the pre-reaction zone from the deposition zone allows the precursors to react in the deposition zone and uniformly distribute the reacted intermediate species on the substrate to be CVD-coated. The size of the zones, and thus the residence time in each zone, may be controlled by varying system variables including but not limited to the chamber pressure, the substrate temperature, the reactant feed rates, the size and shape of the substrate.

In the first embodiment, the means to form reaction intermediates comprises at least a gas distribution medium, forming two spatially separate zones, one is a preheating zone for the pre-heating of reactants and/or the formation of the volatile reaction intermediates, the second zone is a deposition zone for the subsequent distribution or deposition of the reacted precursors, i.e., the CVD coating layer on the substrate. In a second embodiment, the means to produce separate pre-reaction and deposition zones comprises a plurality of injectors for the reactants to pre-react prior to the deposition phase.

In one embodiment, the reactant feed material is an organic or a non-organic compound which is capable of reacting, including dissociation and ionizing reactions, to form a reaction product which is capable of depositing a coating on the substrate. The reactant may be fed as a liquid, a gas or, partially, as a finely divided solid. When fed as a gas, it may be entrained in a carrier gas. The carrier gas can be inert or it can also function as a fuel. In one embodiment, the reactant material is in the form of droplets, fed to the downstream, temperature-controlled chamber, where they evaporate. In yet another embodiment, the reactant material is introduced directly to the chamber through a gas inlet mean.

The deposited coating which can be applied by the inventive apparatus and process of the invention can be any inorganic or organic material that will deposit from a reactive precursor material. Examples include metals, metal oxides, sulfates, phosphates, silica, silicates, phosphides, nitrides, borides and carbonates, carbides, other carbonaceous materials such as diamonds, and mixtures thereof are inorganic coatings. Organic coatings, such as polymers, can also be deposited from reactive precursors, such as monomers, by those embodiments of the invention which avoid combustion temperatures in the reaction and deposition zones.

The coating can be deposited to any desired thickness. In one embodiment, the coating deposit comprises one or more layers on the substrate, for a substantially uniform chemical modification of the substrate. In one embodiment, highly adherent coatings at thicknesses between 10 nanometers and 5 micrometers are formed.

The substrates coated by the inventive apparatus/process of the invention can be virtually any solid material, including metal, ceramic, glass, etc. In one embodiment, the process of the invention is for the fabrication of carbon doped pyrolitic boron nitride (CPBN) based heaters and chuck used in semiconductor wafer processing equipment. In another embodiment, the process is for the fabrication of freestanding shapes, including but not limited to the fabrication of pyrolitic boron nitride (PBN) vertical gradient freeze (VGF) crucibles or liquid-encapsulated Czochralski (LEC) crucibles, for use in the fabrication of compound semiconductor wafers.

In the first embodiment, after the pre-reaction zone, the gaseous intermediates are distributed by the gas diffuser plate/distribution medium over the heated substrate in such a fashion that uniform coating of the substrate occurs in the substrate treatment zone or deposition zone. The gas distribution medium allows a substantially uniform deposit formed on the substrate.

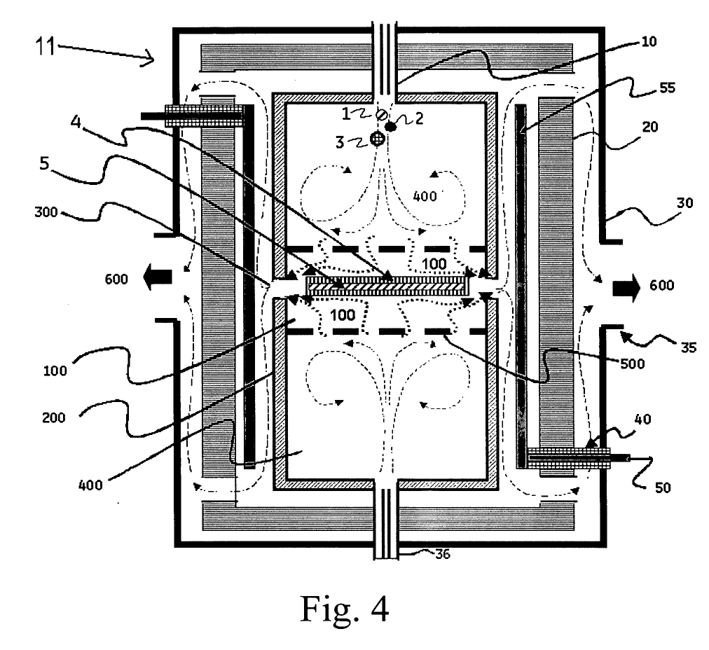

FIG. 4 is a schematic sectional view of the first embodiment of the CVD chamber 11 of the invention. The reactant supply system (not shown) having a plurality of feedlines for supplying reactants to the chamber 11 through entry port 10. In one embodiment, the entry port 10 is also coupled to a cleaning source (not shown), which provides a cleaning agent that can be periodically introduced into the chamber to remove deposition byproducts and films from the processing chamber hardware. In another embodiment, the input reactant is first atomized prior to entering the chamber through entry port 10. Atomizing can be done using techniques known in the art, including heating the reactant feed to a temperature within 50° C. of its critical temperature prior to flowing it through a hollow needle or nozzle with a restricted outlet, etc. In yet another embodiment, the starting reactant may be in solids which then sublime to form reaction gases.

In one embodiment, the chamber 11 comprises a water-cooled metal vacuum vessel with a water-cooled outer chamber wall, although other means for cooling can also be used. The chamber wall is typically fabricated from aluminum, stainless steel, or other materials suitable for high temperature corrosive environments. Inside the chamber wall, the vessel is provided with resistive heating elements 55 and thermal insulation 20 as outer layers. In one embodiment, resistive elements 55 and insulation layers 20 are also provided at the top and bottom of the chamber 11 to further control the heat supply to the chamber.

Resistive heating elements 55 are coupled to a power supply (not shown) to controllably heat the chamber 11. Electrical feedthroughs 40 house the electrical contact 50 between the power supply and the resistive heater elements in the vessel, allowing the resistive heating elements 55 to heat the inner chamber wall, including the substrate, to an elevated high temperature of at least 700° C., depending on the deposition processing parameters and the applications of the materials being deposited, e.g., a pBN crucible or a coating a heater substrate. In one embodiment, the heater 55 maintains the substrate 5 temperature to at least about 1000° C.

In one embodiment, a “muffle” cylinder 200 is disposed next to the heating elements 55, defining a heated inner chamber wall. In one embodiment, the cylinder 200 is made out of graphite or sapphire for low temperature as well as high temperature applications, including high temperature CVD applications of >1400° C. In another embodiment, the cylinder 200 comprises a quartz material for CVD applications <1400° C. The cylinder 200 is provided with at least one exhaust gap or outlet 300 at approximately in the center of the cylinder height.

In one embodiment, a substrate 5 is placed at about the same level as the exhaust gap 300. The substrate 5 can be suspended from the top of chamber 11 by a plurality of rods, or it may be supported by a support assembly (not shown) connected to the sidewall of cylinder 200. In yet another embodiment, the support assembly comprises a stem coupled to a lift system (not shown) allowing positioning the substrate at a desired level within the chamber. In another embodiment for use in depositing pBN crucibles, a mandrel is placed in place of the substrate 5. The mandrel can be suspended from the top of a chamber 11 by a plurality of rods as with a substrate.

In one embodiment, the chamber 11 is provided with at least a gas distribution medium 500, located at a predetermined distance from the substrate, comprising a material such as graphite, quartz glass, aluminum oxide, and the like, etc, able to withstand highly corrosive/high temperature environments. The gas distribution medium 500 is fastened to the cylinder 200 by means of fastening means such as screws, fasteners, and the like. In another embodiment, a hanger plate (not shown) is used to suspend the distribution medium and maintain the distribution medium 500 in a spaced-apart relation relative to the substrate 5. The hanger plate and/or the fastening means comprise materials that can withstand high temperature corrosive environments, e.g., NH₄, BCl₃, HCl, such as tungsten, refractory metals, other RF conducting materials.

In one embodiment, the gas distribution medium 500 comprises a graphite plate located parallel to the substrate and having a predetermined hole pattern. The plate is of a sufficient thickness as not to adversely affect the substrate processing. In one example, the plate has a thickness of about 0.75 to 3 inches. In another example, between 1 to 2 inch thick. In yet another embodiment, the gas distribution medium comprises a plate fabricated from tungsten, refractory metals, other RF conducting materials.

With respect to the hole pattern in the gas distribution medium, in one embodiment, the gas distribution plate is defined by a plurality of gas passages or holes. The holes may be tampered, bored, beveled, or machined through the plate and of sufficient size as not to restrict the flow of the reactants and/or volatile reaction intermediates onto the substrate. In one embodiment, the hole sizes range from about 0.05″-0.25″ in diameter. In another embodiment, the holes are of different sizes and distributed evenly on the distribution plate. In one embodiment, the hole is of a uniform diameter from the inlet to outlet side. In yet another embodiment, the hole are of a flared pattern (truncated cone shape) with the hole diameter increasing from the inlet size to the outlet size, depending on the location of the perforated hole for a uniform deposition rate on the substrate located below the gas distribution plate. In one embodiment, the hole is flared at about 22 to at least about 35 degrees.

In one embodiment of the invention, the gas distribution medium is placed at a distance sufficient further away from the substrate and the gas inlet to enable the pre-heating and/or pre-reaction of the reactants and/or the uniform formation of reaction intermediates on the substrate. By “sufficient distance away from the substrate” herein means a length of a sufficient distance away to allow the substrate to have relatively uniform coating thickness, i.e., a thickness difference of less than 10% between two extreme thickness locations in the coating of the substrate (of the same side, either top or bottom side of the substrate). In another embodiment, the coating has a uniform thickness of less than 10% variation expressed as ratio of standard deviation to average of the thicknesses on one side of the substrate.

The gas distribution medium 500 defines two areas or zones within the chamber 11, a deposition zone 100 and a pre-reaction zone 400.

In one embodiment, the gas distribution medium is placed at a position between ½ to 9/10 of the length between the gas inlet and the substrate. In another embodiment, the gas inlet is placed at a position of about ⅔ to ⅘ of the length.

The chamber 11 is provided with at least an entry port 10, through which a plurality of reactant feeds are introduced via mechanical feedthroughs (not shown) into the cylinder 200. In one embodiment of the process of the invention, a plurality of reactant feeds 1 and 2 are injected into the vessel through the entry port 10 and heat up and/or substantially pre-react forming intermediate precursors 3 in the pre-reaction zone 400. The pre-heated/pre-reacted liquid is then distributed over the heated substrate 5 via gas distribution medium 500, where it forms a substantially uniform deposit 4. In one embodiment of the invention, the chamber 11 comprises two gas distribution medium or plates 500 placed at equi-distance from the substrate 5. In another embodiment (not shown), only one gas distribution medium 500 is used. In yet another embodiment (not shown), the two gas distribution plates 500 are placed at different interval distances from the substrate 5, allowing controlled deposition of the coating on the substrate depending on the application with different coating thicknesses or uniformity on each side of the substrate.

Undeposited products and remaining gases are exhausted through the exhaust gap 300 in the center of the graphite cylinder. The exhausting gases are transported to another mechanical feedthrough 35 that is in fluid communication with an exhaust line. The exhaust line leads to a pumping system (not shown), comprising valves and pumps, that maintains a predetermined pressure in the exhaust line 600.

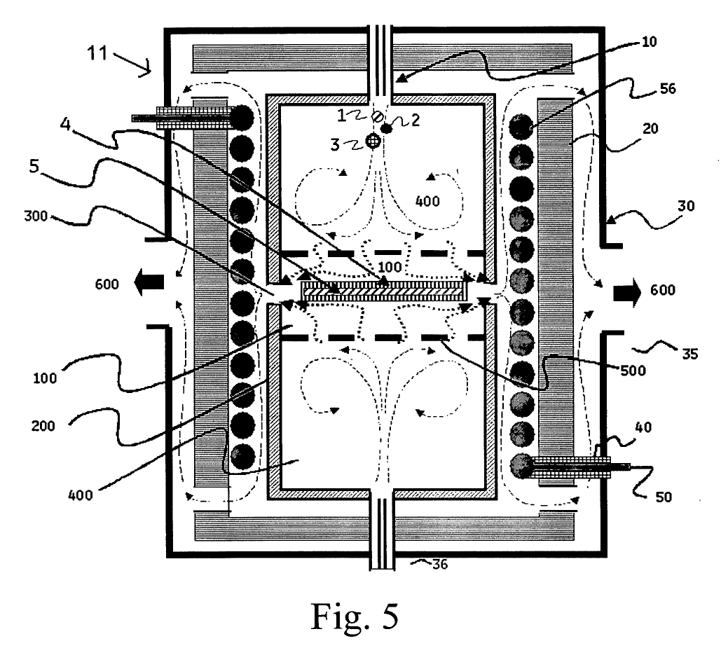

FIG. 5 illustrates another embodiment of the invention, wherein the apparatus comprises an inductive heating system. In the apparatus, a chamber 11 houses cylinder 200, wherein a flat substrate 5 is horizontally mounted between two gas distribution plates 500, with the at least one exhaust gap or hole 300 being located to the side. The exhaust holes 300 are located at about mid-way of the cylinder length, at close proximity to the substrate. In this embodiment, the apparatus 11 comprises an inductive heating system 56 (as opposed to resistive heating elements). Inductive power is coupled from an induction coil to the substrate and the heated inner wall 200, with the gas distribution medium 500 defining the pre-reaction zone and the deposition zone. Other elements described in the previous embodiment of FIG. 4 are also comprised in this embodiment. In another embodiment of the invention (not illustrated here), inductive heating may be used in conjunction with a resistive heating system.

In a second embodiment of the high temperature CVD apparatus of the invention, the gas-phase pre-reaction zone is spatially separate from the deposition zone not via a physical means such as a distribution medium, but through a plurality of input or feed jets (nozzles), defining an interaction zone or a pre-reaction zone for the input reactants fed via the plurality of the jets.

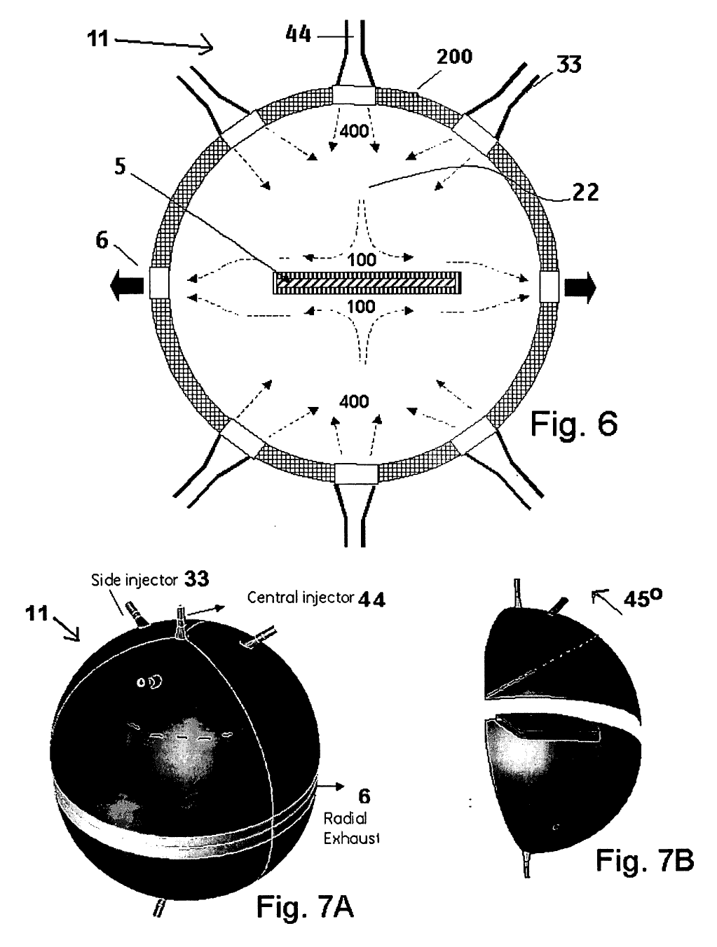

In one embodiment as illustrated in FIG. 6, the jets are positioned such that the reactant gases are injected through the jets into a jet interaction zone, i.e., a common collision area in the chamber 11, wherein the reactant gases pre-react, defining a pre-reaction zone 400 that is locationally separate from the deposition zone 100 near the substrate. As illustrated in FIG. 6, the inlet side of the jets are flush with the chamber inner surface. In another embodiment (not shown), the jets have the shapes of nozzles having narrow tips protruding into the chamber inner surface and wherein the nozzle tips can be tilted or moved defining the jet-interaction zone where the pre-reaction takes place.

In one embodiment, the plurality of gaseous jets are aligned in a manner for the jet interaction of the reactants to occur at a point or location remote from the substrate location. In one embodiment, the remote point is defined by the intersection of the center lines through the plurality of the jets, for a point that is spatially away from the substrate 5. In another embodiment, the jet interaction is achieved by directing multiple gaseous side injectors 33 towards each other, defining a pre-reaction zone 400.

In one embodiment as illustrated in FIG. 7(a), the central injector 44 can be used to inject either diluent gases (including but not limited to N₂) or reactant gases. In another embodiment, a gas distribution medium (not shown) can also be used in conjunction with the jets, separating the pre-action zone and the deposition zone for uniform distribution of the gaseous precursor on the freestanding substrate 5. Undeposited products and unreacted gases exit from radial exhaust 6.

In yet another embodiment (not illustrated), the chamber 11 comprises a vacuum vessel and a plurality of side gas injector and without any central injector. In a second embodiment, the chamber 11 comprises an array of jets or injectors (not shown), with multiple jets for each reactant feed, and with the injectors spread equidistant in an area by an angle of 45 to 135 degree from the substrate 5 as indicated by the dotted line in FIGS. 7(a) and 7(b).

In one embodiment, the substrate 5 is supported by a support assembly having a built-in heater, with the support assembly being connected to the sidewall of the vacuum vessel by fastening means known in the art. In another embodiment (not shown), the vacuum vessel further comprises a resistive heater disposed within and conforming to the shape of the vacuum vessel, for heating the vacuum vessel and the substrate to the CVD temperature of at least 700° C. In yet another embodiment, an insulation layer (not shown) is further provided surrounding the resistive heater.

The pre-reaction rate can be controlled by varying the operating parameters including the diameters of the reactant-supplying nozzles or jets, the pump pressure, the temperatures and concentrations of the starting reactants, the quantity of reactant gases, and the residence time of the reactants in the pre-reacting zone. In one embodiment, the side and central injector positions and the reactant flow rates are controlled while maintaining a uniform concentration of the gaseous pre-cursor near the substrate to: a) increase the residence times for heating the gases and/or achieving conversion of reactant gases to gaseous pre-cursor; and/or b) reduce the residence times to minimize the gas-phase nucleation in the pre-reacting zone. In another embodiment, the angle of the side injectors is optimized for high and uniform deposition rates on the substrate. For example, very large angles of the side injectors with central injector may result in good mixing and conversion to volatile reaction intermediates. However, they may also result in unwanted high deposition rates in the chamber wall 1. Very small angles on the other hand, can adversely affect the efficiency of jet-interaction resulting in poor conversion of the reactants to volatile reaction intermediates.

The plurality of jets or nozzles can be of the same or different sizes. In one embodiment, the jet or nozzle diameter is 0.01″ to 5″. In a second embodiment, from 0.05 to 3″. In a third embodiment, from 0.1″ to 0.3″ μm. In one embodiment, the throughput through all the nozzles is 1 to 50 slm (standard liters per minute). In another embodiment, 10 to 20 slm.

The chamber 11 of the invention (and the cylinder or vacuum vessel 200 disposed within) can be of a cylinder shape, or any other geometries including that of a spherical shape. Furthermore, more than one gas injector may be used and that the injector(s) maybe located at various locations in the vacuum vessel. Additionally, the gas exhaust port(s) or hole(s) may be located along the vacuum vessel for multiple gas exhaust zones and at different height levels approximately close to the height level of the substrate 5.

### EXAMPLES

Examples are provided herein to illustrate the invention but are not intended to limit the scope of the invention.

### Example 1

In an illustrative example of a process to deposit layers in an apparatus as shown in FIG. 4, the heated inner wall 200 is first heated to 1910° C. The pressure in the exhaust line is controlled to a pressure in the 300 to 450 m Torr range. Gaseous feed BCl₃ is supplied at 1.2 slm; NH₃ is fed at 4.5 slm; and N₂ is fed at 0.9 slm through both the top and the bottom injectors each. The pre-reaction and deposition zones are defined by two plates, each having holes arranged in a pattern of 3 concentric circles with diameters of 3, 6.5 and 10 inch. There are 8 holes with a diameter of 0.56″ on the inner circle. There are 16 holes of 0.63″ diameter on the middle circle. There are 24 holes with 0.69″ diameter on the outer circle. The plates are located parallel to the substrate at 5″ distance from the substrate surface on each side of the substrate.

Computation Fluid Dynamics (CFD) calculations are also carried out for this example. The apparatus inner surfaces and the substrates are assumed to be at the operating temperature (=1910° C.). The radiation will have a strong effect in minimizing any temperature differences between the solid surfaces at this high operating temperature. The gaseous reactants are assumed to enter the apparatus at room temperature. Kinetic theory is used for the calculation of the gaseous properties. A two-step reaction mechanism for PBN deposition is considered

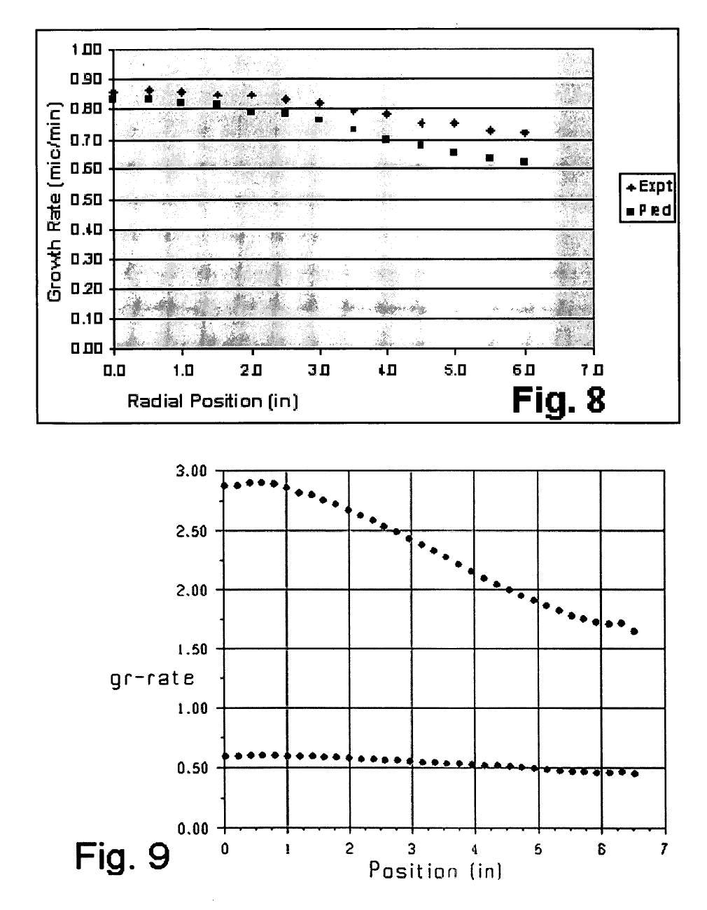

FIG. 8 is a graph validating the CFD model calculations, showing that the measured thickness profile is close to the predicted profile. In the figure (and subsequent figures), “gr-rate” refers to growth rate on the substrate in microns per min, and “position” refers to the location from the center of the substrate (in inches). The uniformity is less than 10% standard deviation to average thickness ratio, a substantial improvement from the non-uniform profiles that would be obtained with the prior art embodiment.

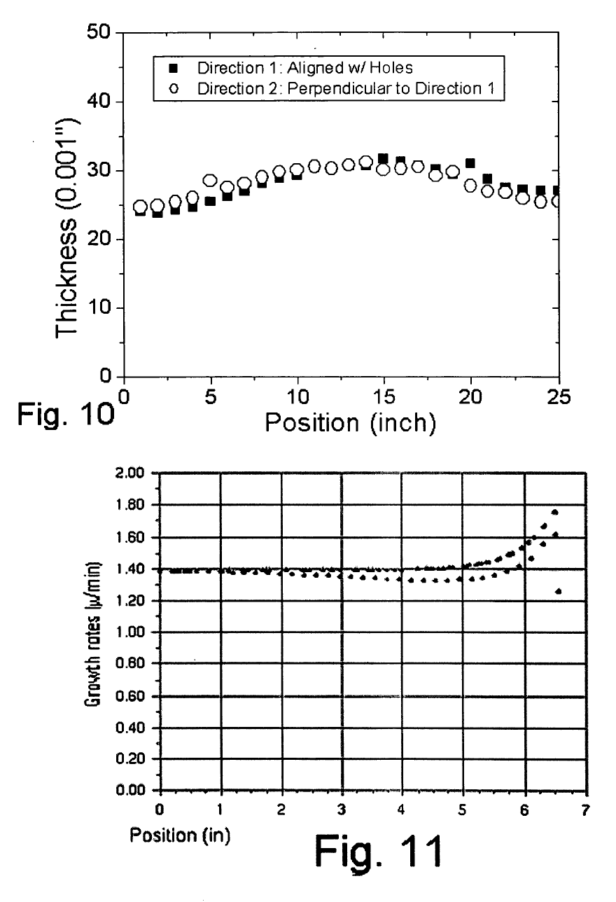

FIG. 10 is a graph illustrating experimental results of the deposition profiles obtained for Example 1, showing substantially uniform distribution on the substrate. Direction-1 is along the line of the exhaust port or vacuum arm while Direction-2 is perpendicular to it.

### Example 2

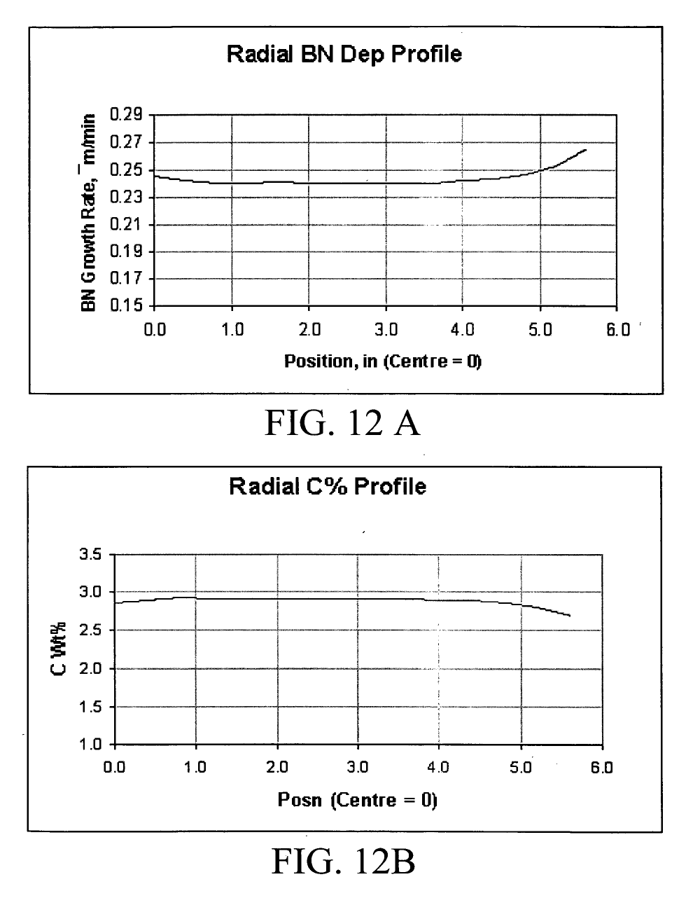

Computational fluid dynamic (CFD) calculations are carried out to model a CVD process in the chamber of FIG. 4, depositing carbon-doped pyrolitic boron nitride (CPBN) on a substrate. The model as illustrated in FIG. 12 again predicts a substantially uniform growth rate and thickness profile, i.e. less than 10% standard deviation to average thickness ratio, but also a substantially uniform carbon concentration profile, i.e. less than 10% standard deviation to average carbon concentration ratio. This is a substantial improvement from the non-uniform profiles of the prior art (as illustrated by the graph of FIG. 9).

As indicated in FIG. 12, CFD alculations of the deposition rate and carbon concentration profiles carbon-doped PBN (CPBN) deposition show that substantially uniform deposition rate (and thus thickness) and carbon concentration profiles can be achieved on the substrate using the apparatus and process of the invention.

### Example 3

This example illustrates a process to deposit pyrolytic boron nitride layers in an apparatus as shown in FIG. 6 (and also FIG. 7), wherein pre-reaction zone or jet interaction zone is formed by the multiple reactant jets from the gas injectors inside a hemispherical reactor made of graphite. There are three side injectors and one central injector on each side of the substrate (in the form of a circular disk). The side injectors are equally spaced around the central injector. Each side injector is at an angle of 60 degrees from the central injector.

First, the inner wall of the apparatus is heated to 1800° C. The pressure in the exhaust line is controlled at about 350 mTorr. Total gaseous feed of BCl₃ is 2.85 slm; NH₃ is fed at 8.4 slm; and N₂ is fed at 6.75 slm, through all the central and side injectors. As illustrated in FIG. 11, the jet interaction results in efficient heating and mixing of the reactants to form the volatile reaction intermediate resulting uniform deposition (<10%).

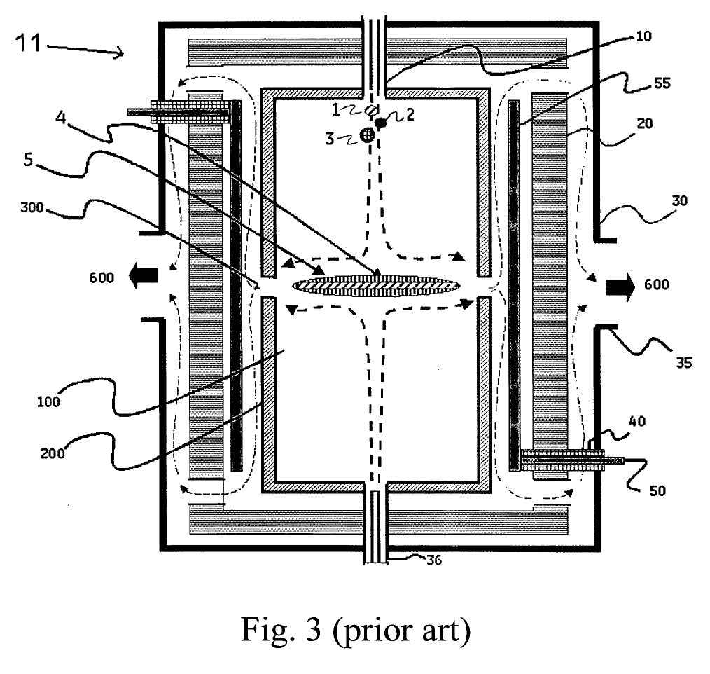

In the FIG. 11, deposition rate profiles along two radial lines is shown which have maximum differences resulting from the non-axisymmetric locations of the side injectors. This maximum difference also is within the desired limits for non-uniformity. This is a substantial improvement from the non-uniform profiles that would be obtained with the prior art embodiment of FIG. 3.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims. All citations referred herein are incorporated by reference.

1. A chemical vapor deposition (CVD) system comprising:
a vacuum reaction chamber, in which at least a substrate which is to be coated is disposed within and wherein the vacuum reaction chamber is maintained at a pressure of less than 100 torr;
a reactant supply system, having at least an inlet unit connected thereto for providing a plurality of reactant feeds to the reaction chamber;
an outlet unit in fluid communication with the reaction chamber;
means for defining a volume space in the reaction chamber for pre-reacting the reactant feeds forming at least a reaction precursor in a gaseous form, and a volume space for depositing a coating layer on the substrate from reacted precursor; and
heating means for maintaining the substrate at a temperature of at least 700° C.

2. The CVD system of claim 1, wherein the means for defining a volume space for pre-reacting the reactant feeds and a volume space for forming a coating layer comprises a distribution means for separating the pre-reaction volume space and the deposition volume space.

3. The CVD system of claim 2, wherein the distribution means comprises at least a plate having a plurality of holes or passages for distributing the reacted precursor on the substrate, forming a coating layer;
wherein the distribution plate is located in between the inlet unit and the substrate, of a sufficient distance away from the substrate for the coating layer to be uniformly deposited on the substrate.

4. The CVD system of claim 3, wherein the distribution means comprises two distribution plates placed at equi-distance from the substrate.

5. The CVD system of claim 2, wherein the distribution plate is at a sufficient distance away from the substrate for the coating layer on the substrate to have a coating thickness variation of less than 10%.

6. The CVD system of claim 5, wherein the distribution plate is placed at a position between ½ to 9/10 of a length between the inlet unit and the substrate.

7. The CVD system of claim 6, wherein the distribution plate is placed at a position between ⅔ to ⅘ of the length between the inlet unit and the substrate.

8. The CVD system of claim 3, wherein the distribution plate comprises a plurality of passages of sufficient sizes for the distribution of the reacted precursor on the substrate, forming a coating layer with a coating thickness variation of less than 10%, as expressed as a ratio of standard deviation to average.

9. The CVD system of claim 3, wherein the distribution plate comprises a plurality of passages of sufficient sizes for the distribution of the reacted precursor on the substrate, forming a coating layer with a coating thickness variation of less than 5%, as expressed as a ratio of standard deviation to average.

10. The CVD system of claim 1, wherein the two reactant feeds to the reaction chamber comprise a feed of BCl₃ and a feed of NH₃.

11. The CVD system of claim 1, wherein the reaction precursor in a gaseous form comprises Cl₂BNH₂.

12. The CVD system of claim 1, for the deposition of a coating layer of pyrolytic boron nitride formed on the substrate from reacted precursor on the substrate.

13. The CVD system of claim 1, for the deposition of a coating layer of aluminum nitride formed on the substrate from reacted precursor on the substrate.

14. The CVD system of claim 1, wherein the substrate is in the form of a heater, a disk, a crucible, or a mandrel.

15. The CVD system of claim 1, wherein the heating means for maintaining the substrate at a temperature of at least 700° C. comprises at least one of an induction heating element and a resistive heating element.

16. The CVD system of claim 15, wherein at least a resistive heating element is used for maintaining the substrate at a temperature of at least 1000° C.

17. The CVD system of claim 2, wherein the distribution means comprises a plurality of jet injectors for feeding the reactants to the chamber and for defining a jet interaction zone, wherein the reactants pre-react forming reaction intermediates.

18. The CVD system of claim 17, wherein the plurality of jet injectors comprise a central jet injector and at least two side jet injectors, each jet injector having an outlet discharging reactants into the chamber.

19. The CVD system of claim 17, wherein the jet interaction zone is located between the jet injector outlets and the substrate, at a sufficient distance away from the substrate for uniform deposition of reacted intermediates onto the substrate forming a coating layer with a coating thickness variation of less than 10%.

20. The CVD system of claim 17, wherein the jet injectors have an average jet nozzle diameter of 0.01″ to 5″.

21. The CVD system of claim 21, wherein the jet injectors have an average jet nozzle diameter of 0.05 to 3″.

22. The CVD system of claim 17, wherein the jet injectors have an average feed throughput of 1 to 50 standard liters per minute.

23. The CVD system of claim 17, wherein the plurality of jet injectors are spatially spaced on a top surface of the chamber, as formed at an angle of 45 to 135 degree of the substrate located horizontally in the chamber.

24. The CVD system of claim 17, further comprising a heating means for maintaining the substrate at a temperature of at least 700° C., and wherein the heating means is selected from at least one of an induction heating element and a resistive heating element.

24. The CVD system of claim 17, wherein the substrate is in the form of a heater, a disk, a crucible, or a mandrel.

25. The CVD system of claim 17, wherein the plurality of jet injectors comprise a center jet nozzle for feeding an inert gas to the chamber.

26. The CVD system of claim 17, wherein the chamber is spherical in shape.

27. A chemical vapor deposition (CVD) process comprising:
providing a reactant supply system for providing a plurality of reactant feeds in a fluid medium form;
providing a substrate having a substrate to be CVD coated in a vacuum reaction chamber maintained at less than 100 torr, heating the substrate to a temperature of at least 700° C., causing the reactant feeds to pre-react in a defined zone, forming reaction intermediates in gaseous form,
causing the intermediates to react, wherein the reaction of the intermediates is confined in a zone spatially separate from the pre-reaction zone, depositing a layer on the substrate having a thickness variation of less than 10%.

28. The method of claim 27, wherein the pre-reaction zone is spatially defined from the substrate deposition zone by a distribution plate, and wherein the distribution plate comprises a plurality of passages of sufficient sizes for the deposition of the reacted intermediates on the substrate forming the coating layer.

29. The method of claim 27, wherein the pre-reaction zone is spatially defined from the deposition zone by a plurality of jet injectors for feeding reactants to the chamber, and wherein the plurality of jet injectors cause a jet-interaction area to be formed, wherein the reactants pre-react forming the pre-reaction zone.

30. The CVD system of claim 1, wherein the vacuum reaction chamber is maintained at a pressure of less than 10 torr.

31. The CVD process of claim 27, wherein the substrate is CVD coated in a vacuum reaction chamber maintained at less than 10 torr.

32. A chemical vapor deposition (CVD) system comprising:
a vacuum reaction chamber, in which at least a substrate which is to be coated is disposed within and wherein the vacuum reaction chamber is maintained at a pressure of less than 100 torr;
heating means for maintaining the substrate at a temperature of at least 700° C.
a reactant supply system, having at least an inlet unit connected thereto for providing a plurality of reactant feeds to the reaction chamber;
an outlet unit in fluid communication with the reaction chamber;
at least a distribution plate located in between the inlet unit and the substrate, of a sufficient distance away from the substrate, wherein the distribution plate defines a volume space in the reaction chamber for pre-reacting the reactant feeds forming at least a reaction precursor in a gaseous form and a volume space for depositing a coating layer formed from the reacted precursor onto the substrate, and wherein the distribution plates has a plurality of holes or passages for distributing the reacted precursor onto the substrate for the coating layer to have a thickness variation of less than 10%.

33. A chemical vapor deposition (CVD) system of claim 32, wherein the reaction chamber is maintained at a pressure of less than 10 torr and the substrate is heated to a temperature of at least 700° C. by at least a resistive heating element.

34. A chemical vapor deposition (CVD) system comprising:
a vacuum reaction chamber, in which at least a substrate which is to be coated is disposed within and wherein the vacuum reaction chamber is maintained at a pressure of less than 100 torr;
heating means for maintaining the substrate at a temperature of at least 700° C.
a reactant supply system, having a plurality of jet injectors connected thereto for feeding a plurality of reactants to the chamber;
an outlet unit in fluid communication with the reaction chamber;
wherein the jet injectors cause the reactants to pre-react in a volume space in the chamber forming at least a reaction precursor in a gaseous form and
wherein the pre-reaction space is located between the jet injectors and the substrate, at a sufficient distance away from the substrate for the precursor to react forming a coating layer on the substrate and for the coating layer to have a thickness variation of less than 10%.

35. A chemical vapor deposition (CVD) system of claim 34, wherein the reaction chamber is maintained at a pressure of less than 10 torr and the substrate is heated to a temperature of at least 700° C. by at least a resistive heating element.
